(19) United States
(12) Patent Application Publication
(10) Pub. No.: US 2025/0015159 A1
(43) Pub. Date: Jan. 9, 2025

(54) VARACTORS HAVING INCREASED TUNING RATIO

(71) Applicant: Taiwan Semiconductor Manufacturing Company, Ltd., Hsin-Chu (TW)

(72) Inventors: Ming-Shuan Li, Hsinchu County (TW); Zi-Ang Su, Taoyuan County (TW)

(21) Appl. No.: 18/491,486

(22) Filed: Oct. 20, 2023

Related U.S. Application Data
(60) Provisional application No. 63/512,445, filed on Jul. 7, 2023.

(51) Int. Cl. H01L 29/66; H01L 29/06; H01L 29/423

(52) U.S. Cl. CPC H01L 29/66174; H01L 29/0665; H01L 29/42392; H01L 29/66545; H01L 29/6656

(57) ABSTRACT

Semiconductor structures and a method of forming the same are provided. In an embodiment, an exemplary semiconductor structure includes a doped region in a substrate and comprising a first-type dopant, a plurality of nanostructures disposed directly over the doped region, a gate structure wrapping around each nanostructure of the plurality of nanostructures, a first epitaxial feature and a second epitaxial feature coupled to the plurality of nanostructures, wherein each of the first epitaxial feature and the second epitaxial feature comprises the first-type dopant, a first insulation feature disposed between the first epitaxial feature and the doped region, and a second insulation feature disposed between the second epitaxial feature and the doped region.

### PRIORITY DATA

The present application claims the benefit of U.S. Provisional Application No. 63/512,445, filed Jul. 7, 2023, herein incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

MOS (metal-oxide-semiconductor) varactors are semiconductor devices that have a capacitance varying as a function of an applied voltage. Varactors are often used as tuning elements in circuits such as voltage-controlled oscillators (VCOs), parameter amplifiers, phase shifters, phase locked loops (PLLs), and other tunable circuits. For example, by varying a voltage applied to a varactor, the frequency of operation of an associated VCO can be adjusted. Tunability, linearity, and quality factor are among the important characteristics of an MOS varactor. Improvements in tuning ratios of varactors are still desired.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1 is a flowchart illustrating a method of forming a semiconductor structure, according to various aspects of the present disclosure.

FIGS. 2, 3, 4, 5, 6, 7, 8, 9, 10, 11, 12, 13, 14, 15, 16, 17, 18, and 19 illustrate fragmentary cross-sectional views of a workpiece at various stages of fabrication in accordance with the method in FIG. 1, according to various aspects of present disclosure.

FIG. 20A and FIG. 20B illustrate improvements to a tuning ratio of the semiconductor structure, according to various aspects of present disclosure.

FIG. 21 illustrates a fragmentary cross-sectional view of an alternative semiconductor device, according to various aspects of present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

A common element for an advanced electronic circuit and particularly for circuits manufactured as integrated circuits (“ICs”) in semiconductor processes is the use of varactors. Varactors or “variable reactors” provide a voltage-controlled capacitor element that has a variable capacitance based on the voltage expressed at the terminals and a control voltage. Metal oxide semiconductor or MOS varactors may have a control voltage applied to a gate terminal that provides a control on the capacitance obtained for a particular voltage on the remaining terminals of the device. Because a varactor is based on a reverse biased P-N junction, the terminals are typically biased such that no current flows across the junction. A circuit element structure where no current flows between the terminals provides, in essence, a capacitor. By varying the bias on the third terminal (the “gate” for a MOS varactor), the device may form a depletion or even an accumulation region under the gate, changing the current flow through the device. The effective capacitance obtained is thus variable, and voltage dependent. This makes the varactor very useful as a voltage-controlled capacitor. This circuit element is particularly useful in oscillators, radio frequency (RF) circuits, mixed signal circuits and the like.

Multi-gate devices are introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. The channel region of a GAA transistor may be formed from nanowires, nanosheets, other nanostructures, and/or other suitable structures. The shapes of the channel region have also given a GAA transistor alternative names such as a nanosheet transistor or a nanowire transistor.

The present disclosure is directed to methods of forming varactors having a high tuning ratio. In some embodiments, an exemplary method includes forming an insulating layer between the substrate and source/drain features, thereby blocking a current path between the source/drain features and a well region formed in the substrate to set the well region to be electrically floating. Setting the well region to be electrically floating reduces both the maximum capacitance Cmax and the minimum capacitance Cmin, however, the extent at which the minimum capacitance Cmin is reduced is greater than the extent at which the maximum capacitance Cmax is reduced. As a result, the tuning ratio (i.e., Cmax/Cmin) of the varactor is advantageously increased, thereby providing the varactor a larger frequency tuning range.

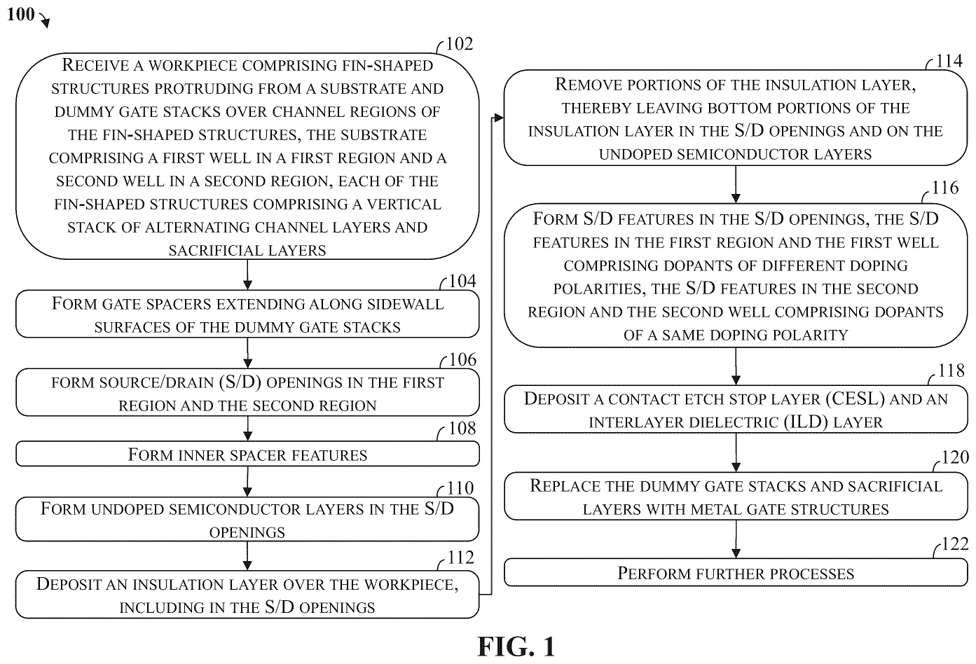

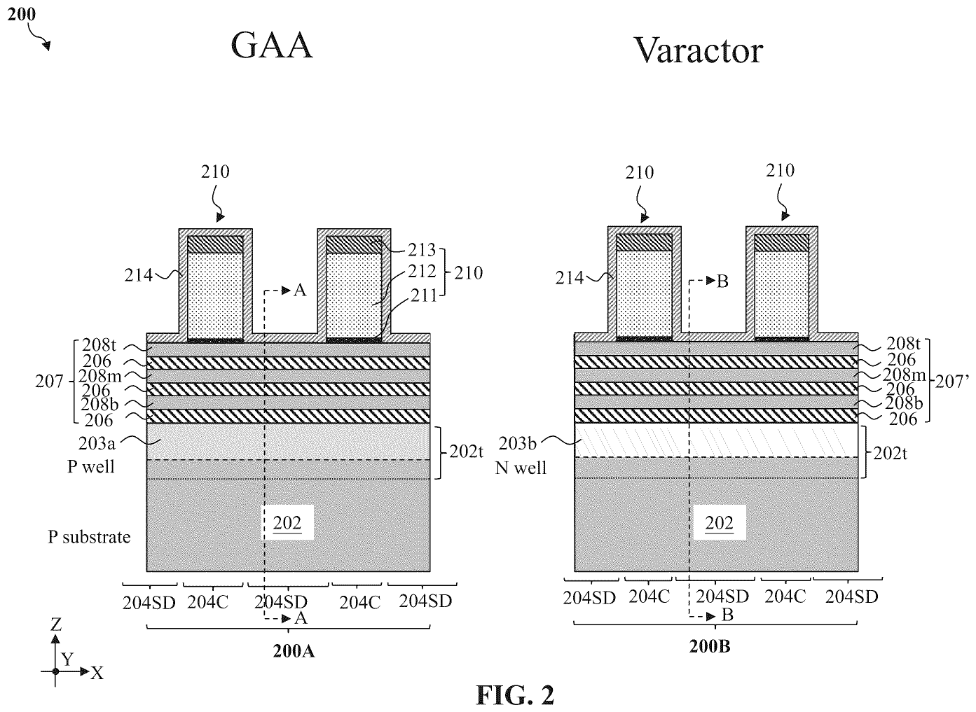

The various aspects of the present disclosure will now be described in more detail with reference to the figures. In that regard, FIG. 1 is a flowchart illustrating a method 100 forming a semiconductor structure according to embodiments of the present disclosure. Method 100 is merely an example and is not intended to limit the present disclosure to what is explicitly illustrated therein. Additional steps can be provided before, during, and/or after the method 100, and some steps described can be replaced, eliminated, and/or moved around for additional embodiments of methods. Not all steps are described herein in detail for reasons of simplicity. Method 100 is described below in conjunction with FIGS. 2-21, which are fragmentary cross-sectional views of a workpiece 200 at different stages of fabrication according to embodiments of the method 100 in FIG. 1 and simulation results. For avoidance of doubts, the X, Y and Z directions in FIGS. 2-19 and 21 are perpendicular to one another and are used consistently throughout FIGS. 2-19 and 21. Because the workpiece 200 will be fabricated into a semiconductor structure, the workpiece 200 may be referred to herein as a semiconductor structure 200 as the context requires. The first region 200A of the workpiece 200 will be fabricated into a semiconductor device (e.g., transistor), the second region 200B of the workpiece 200 will be fabricated into another semiconductor device (e.g., varactor), the first region 200A and the second region 200B may be referred to herein as a semiconductor device 200A or transistor 200A, semiconductor device 200B or varactor 200B, respectively, as the context requires. Throughout the present disclosure, like reference numerals denote like features unless otherwise expressly excepted.

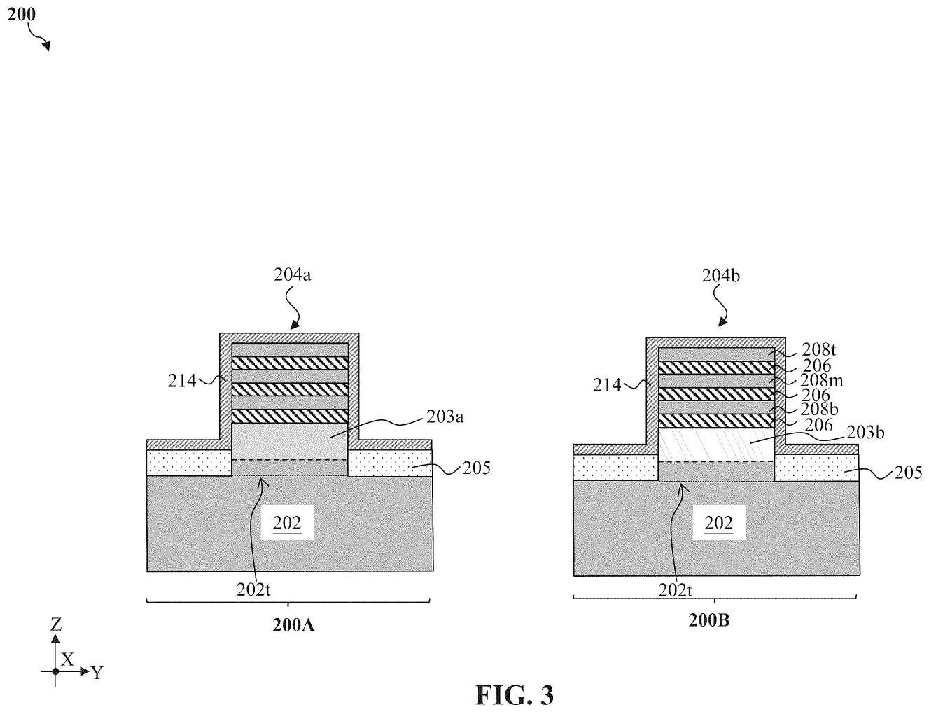

Referring now to FIGS. 1 and 2-3, method 100 includes a block 102 where a workpiece 200 is received. FIG. 3 illustrates cross-sectional views of the workpiece 200 taken along line A-A and B-B as shown in FIG. 2. The workpiece 200 includes a first region 200A and a second region 200B. Upon completion of operations of blocks of method 100, the first region 200A of the workpiece 200 will be fabricated into GAA transistor(s), and the second region 200B of the workpiece 200 will be fabricated into varactor(s).

As depicted in FIGS. 2 and 3, the workpiece 200 includes a substrate 202. In an embodiment, the substrate 202 is a bulk silicon substrate (i.e., including bulk single-crystalline silicon). The substrate 202 may include other semiconductor materials in various embodiments, such as germanium, silicon carbide, gallium arsenide, gallium phosphide, indium phosphide, indium arsenide, indium antimonide, SiGe, GaAsP, AlInAs, AlGaAs, GaInAs, GaInP, GaInAsP, or combinations thereof. In some alternative embodiments, the substrate 202 may be a semiconductor-on-insulator substrate, such as a silicon-on-insulator (SOI) substrate, a silicon germanium-on-insulator (SGOI) substrate, or a germanium-on-insulator (GeOI) substrate, and includes a carrier, an insulator on the carrier, and a semiconductor layer on the insulator. In an embodiment, the substrate 202 is a P-type substrate having a doping concentration in a range between about 10¹⁶ atom/cm³ and 10¹⁷ atom/cm³.

The substrate 202 can include various doped regions configured according to design requirements of semiconductor structure 200. P-type doped regions may include P-type dopants, such as boron (B), boron difluoride (BF₂), other p-type dopant, or combinations thereof. N-type doped regions may include N-type dopants, such as phosphorus (P), arsenic (As), other N-type dopant, or combinations thereof. The various doped regions can be formed directly on and/or in substrate 202, for example, providing a P-well structure, an N-well structure, or combinations thereof. An ion implantation process, a diffusion process, and/or other suitable doping process can be performed to form the various doped regions. In the present embodiments, referring to FIGS. 2 and 3, the substrate 202 includes a first doped portion 203a (or a “first well 203a”) in the first region 200A and a second doped portion 203b (or a “second well 203b”) in the second region 200B. Each of the first well 203a and the second well 203b may be a P-type well or an N-type well, depending upon the types of GAA transistors and varactors formed thereon. In an embodiment, the second well 203b is an N-type well having a doping concentration in a range between about 10¹⁷ atom/cm³ and 1019 atom/cm³. In an embodiment, the second well 203b is a P-type well having a doping concentration in a range between about 10¹⁷ atom/cm³ and 1019 atom/cm³. A doping concentration of the first well 203a may be different than or equal to a doping concentration of the second well 203b.

Still referring to FIGS. 2 and 3, the workpiece 200 includes a vertical stack 207 of alternating semiconductor layers disposed in the first region 200A and a vertical stack 207′ of alternating semiconductor layers disposed in the second region 200B. In an embodiment, each of the vertical stack 207 and the vertical stack 207′ includes a number of channel layers (e.g., channel layers 208t, 208m, 208b) interleaved by a number of sacrificial layers 206. Each of the channel layers 208t, 208m and 208b may include a semiconductor material such as, silicon, germanium, silicon carbide, silicon germanium, GeSn, SiGeSn, SiGeCSn, other suitable semiconductor materials, or combinations thereof, while each sacrificial layer 206 has a composition different from that of the channel layers 208t, 208m and 208b. In an embodiment, each of the channel layers 208t, 208m and 208b includes silicon (Si), the sacrificial layer 206 includes silicon germanium (SiGe). Although the vertical stack 207/207′ of the depicted example includes three channel layers and three sacrificial layers, it is understood that the vertical stack 207/207′ may include any suitable number (e.g., 2 to 10) of channel layers and any suitable number sacrificial layers. In the present disclosure, the vertical stacks 207 and 207′ have the same configuration. In some other embodiments, the vertical stacks 207 and 207′ may have different configurations (e.g., different numbers of channel layers and sacrificial layers, different thicknesses, etc.) The vertical stack 207/207′ and a top portion 202t of the substrate 202 is then patterned to form a first fin-shaped structure 204a (shown in FIG. 3) in the first region 200A and a second fin-shaped structure 204b (shown in FIG. 3) in the second region 200B. In some embodiments, the patterned top portion 202t of the substrate 202 may be referred to as a mesa structure 202t. Dielectric isolation features 205 (shown in FIG. 3) may be formed to isolate two adjacent fin-shaped structures. The dielectric isolation features 205 may also be referred to as shallow trench isolation (STI) features. The dielectric isolation features 205 may include silicon oxide, silicon oxynitride, fluorine-doped silicate glass (FSG), a low-k dielectric, combinations thereof, and/or other suitable materials.

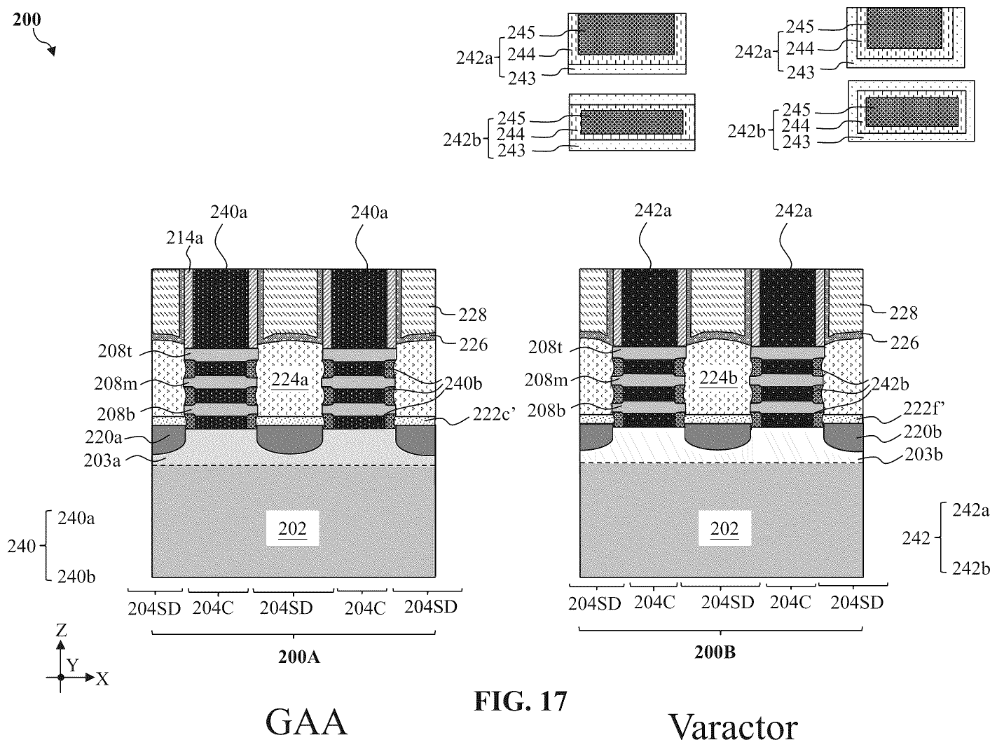

Still referring to FIGS. 2 and 3, the workpiece 200 also includes a number of dummy gate stacks 210 over channel regions 204C of the first fin-shaped structure 204a and the second fin-shaped structure 204b. The channel regions 204C and the dummy gate stacks 210 also define source/drain regions 204SD that are not vertically overlapped by the dummy gate stacks 210. Source/drain region(s) may refer to a source region or a drain region, individually or collectively dependent upon the context. Each of the channel regions 204C is disposed between two source/drain regions 204SD along the X direction. In this embodiment, a gate replacement process (or gate-last process) is adopted where some of the dummy gate stacks 210 serve as placeholders for gate structures 240 and 242 (shown in FIG. 17). Other processes for forming the gate structures 240 and 242 are possible. The dummy gate stack 210 includes a dummy gate dielectric layer 211, a dummy gate electrode layer 212 over the dummy gate dielectric layer 211, and a gate-top hard mask layer 213 over the dummy gate electrode layer 212. The dummy gate dielectric layer 211 may include silicon oxide. The dummy gate electrode layer 212 may include polysilicon. The gate-top hard mask layer 213 may include silicon oxide, silicon nitride, other suitable materials, or combinations thereof.

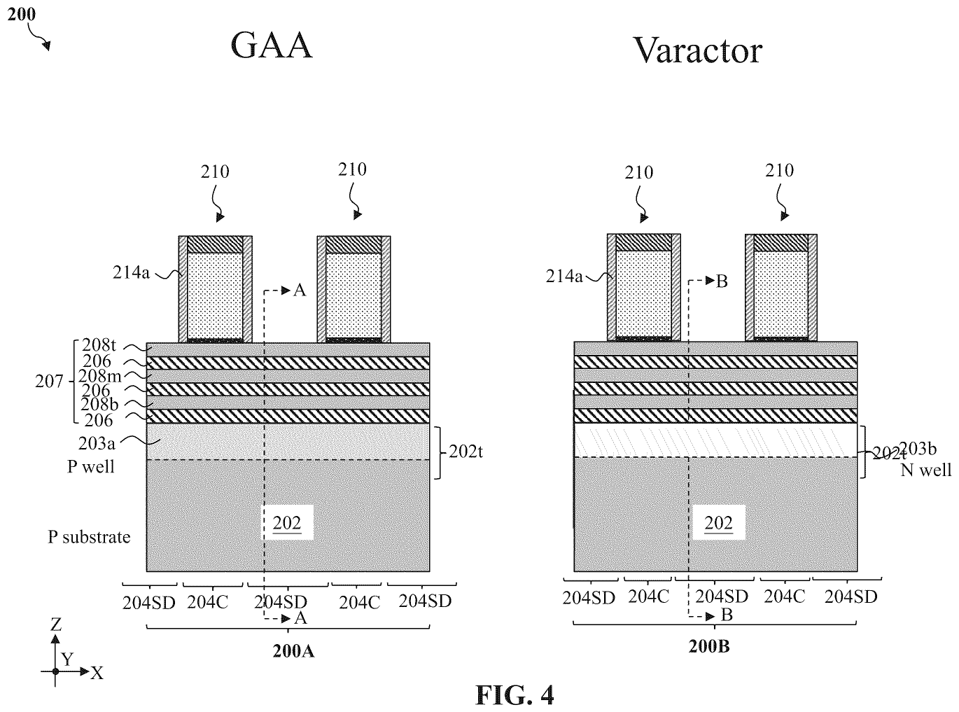

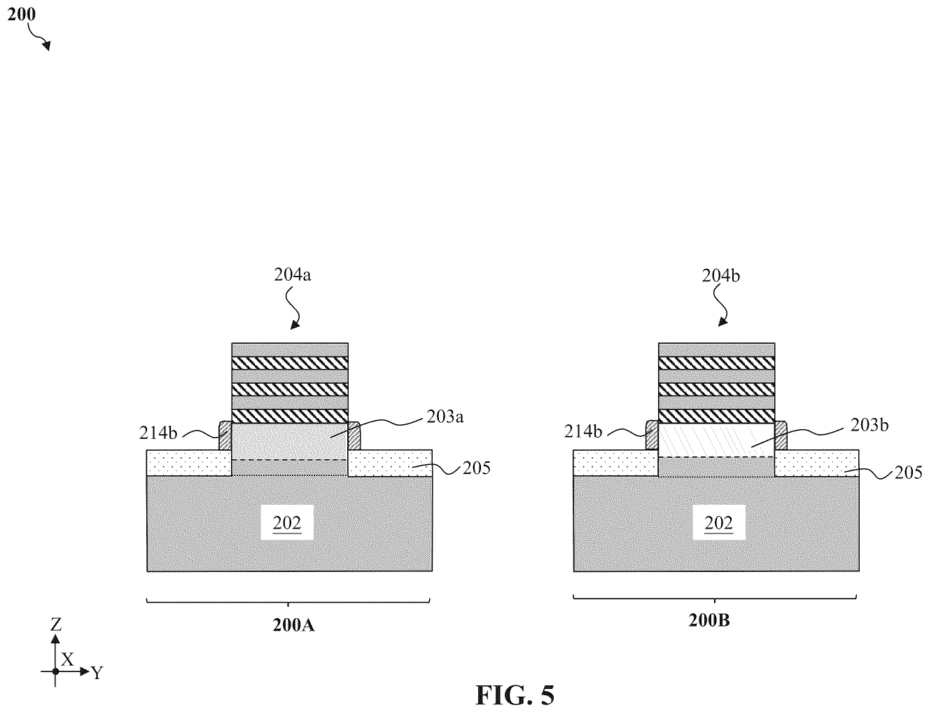

Referring to FIGS. 1 and 2-5, method 100 includes a block 104 where gate spacers 214a are formed to extend along sidewall surfaces of the dummy gate stacks 210. FIG. 5 illustrates cross-sectional views of the workpiece 200 taken along line A-A and B-B as shown in FIG. 4. With reference to FIGS. 2-3, a spacer layer 214 is conformally deposited over the workpiece 200, including over top surfaces and along sidewall surfaces of the dummy gate stacks 210 and the fin-shaped structures 204a-204b. The term “conformally” may be used herein for ease of description of a layer having a substantially uniform thickness over various regions. The spacer layer 214 may be deposited over the workpiece 200 using processes such as chemical vapor deposition (CVD), atomic layer deposition (ALD), physical vapor deposition (PVD), or other suitable process. Dielectric materials for the spacer layer 214 may be selected to allow selective removal of the dummy gate stacks 210 without substantially damaging the spacer layer 214 and selective removal of the source/drain regions 204SD of the fin-shaped structures 204a and 204b without substantially etching the spacer layer 214. Suitable dielectric materials may include silicon nitride, silicon oxycarbonitride, silicon carbonitride, silicon oxide, silicon oxycarbide, silicon carbide, silicon oxynitride, other low-k dielectric materials, and/or combinations thereof. With reference to FIGS. 4-5, after forming the spacer layer 214, an etching process is performed to etch back the spacer layer 214 to form gate spacers 214a along sidewall surfaces of the dummy gate stacks 210 and fin sidewall spacers (FSW) 214b along bottom portions of sidewall surfaces of the fin-shaped structures 204a and 204b. An anisotropic etching process may be performed to selectively remove portions of the spacer layer 214 that are not extending along sidewall surfaces of the fin-shaped structures 204a and 204b and the dummy gate stacks 210, thereby forming the gate spacers 214a along sidewall surfaces of the dummy gate stacks 210 and the fin sidewall spacers 214b along bottom portions of sidewall surfaces of the fin-shaped structures 204a and 204b. The anisotropic etching process may include an anisotropic dry etching process.

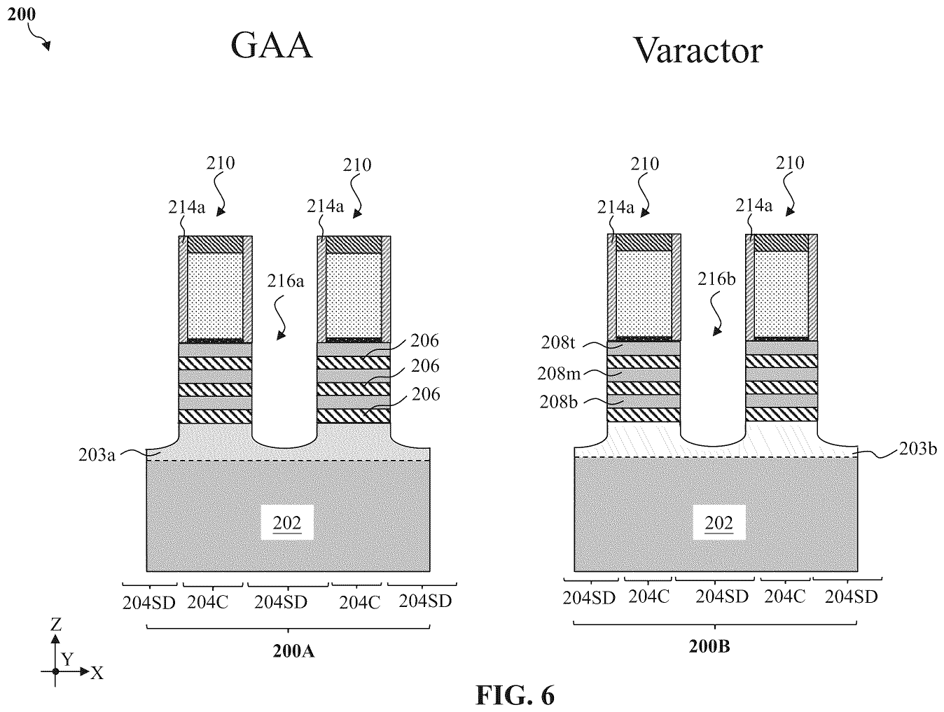

Referring now to FIGS. 1 and 6, method 100 includes a block 106 where source/drain regions 204SD of the fin-shaped structures 204a and 204b are selectively recessed to form source/drain openings 216a in the first region 200A and source/drain openings 216b in the second region 200B. In some embodiments, the source/drain regions 204SD of the fin-shaped structures 204a-204b that are not covered by the dummy gate stacks 210 and the gate spacers 214a are anisotropically etched by a dry etch or other suitable etching process to form the source/drain openings 216a in the first region 200A and the source/drain openings 216b in the second region 200B. As illustrated in FIG. 6, sidewalls of the channel layers (e.g., channel layers 208t, 208m, 208b) and the sacrificial layers 206 are exposed in the source/drain openings 216a/216b. In the present embodiments, the source/drain openings 216a in the first region 200A extend into the first well 203a, and the source/drain openings 216b in the second region 200B extend into the second well 203b.

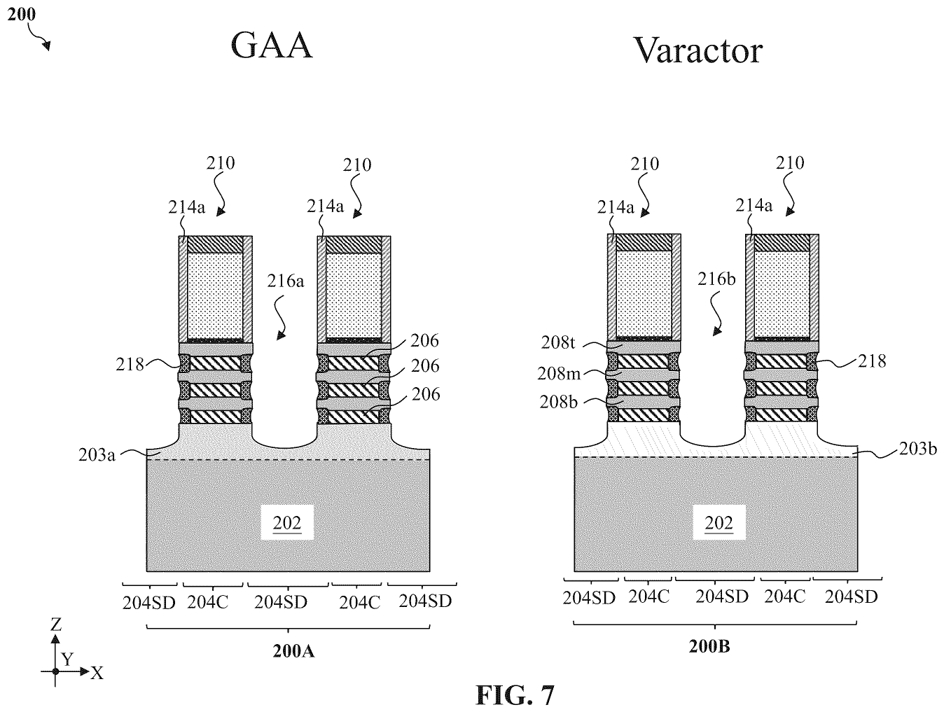

Referring now to FIGS. 1 and 7, method 100 includes a block 108 where inner spacer features 218 are formed. After forming the source/drain openings 216a in the first region 200A and the source/drain openings 216b in the second region 200B, the sacrificial layers 206 exposed in the source/drain openings 216a/216b are selectively and partially recessed to form inner spacer recesses (filled by inner spacer features 218), while the exposed channel layers (e.g., channel layers 208t, 208m, 208b) are substantially unetched. In some embodiments, this selective recess may include a selective isotropic etching process (e.g., a selective dry etching process or a selective wet etching process), and the extent at which the sacrificial layers 206 is recessed is controlled by duration of the etching process. After the formation of the inner spacer recesses, an inner spacer material layer is then conformally deposited using CVD or ALD over the workpiece 200, including over and into the inner spacer recesses. The inner spacer material may include silicon nitride, silicon oxycarbonitride, silicon carbonitride, silicon oxide, silicon oxycarbide, silicon carbide, or silicon oxynitride. The inner spacer material layer is then etched back to form the inner spacer features 218, as illustrated in FIG. 7. In some embodiments, a composition of the inner spacer features 218 is different than a composition of the gate spacers 214a and the fin sidewall spacers 214b such that the etching back of the inner spacer material layer does not substantially etch the gate spacers 214a and the fin sidewall spacers 214b.

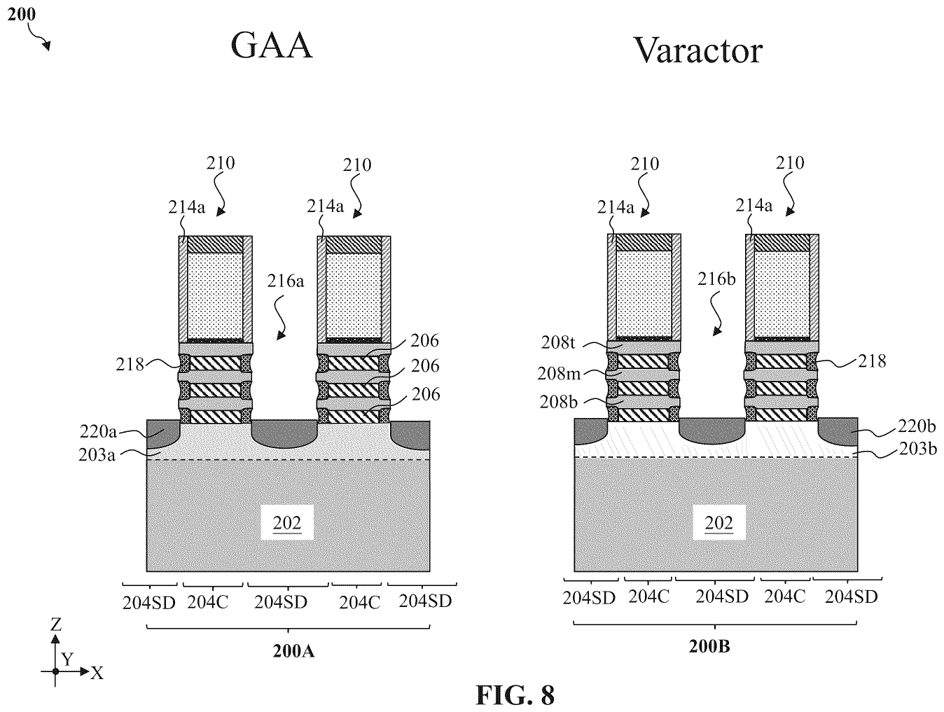

Referring now to FIGS. 1 and 8, method 100 includes a block 110 where semiconductor layers 220 are formed in the source/drain openings 216a and 216b. In the present embodiments, after forming the inner spacer features 218, the semiconductor layers 220a and 220b are formed over top surfaces of the first well 203a and the second well 203b exposed in the source/drain openings 216a and 216b, respectively, by using an epitaxial process. The semiconductor layers 220a and 220b may be undoped or not intentionally doped. In some embodiments, the semiconductor layers 220a and 220b may include undoped silicon (Si), undoped germanium (Ge), undoped silicon germanium (SiGe), or other suitable materials. In an embodiment, the semiconductor layers 220a and 220b are formed simultaneously by a common epitaxial process and include undoped silicon (Si).

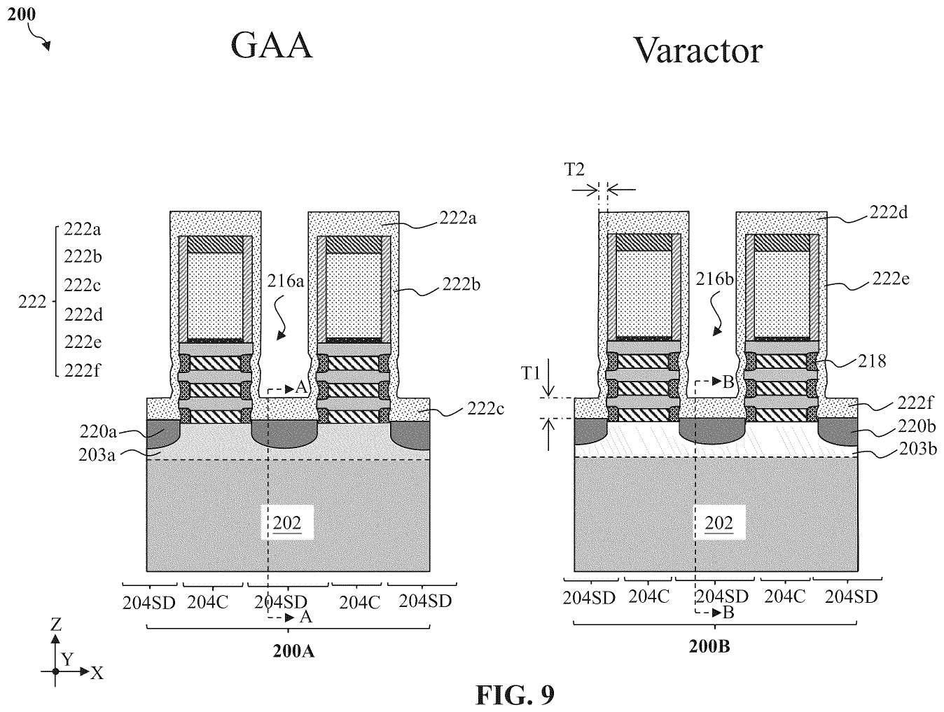

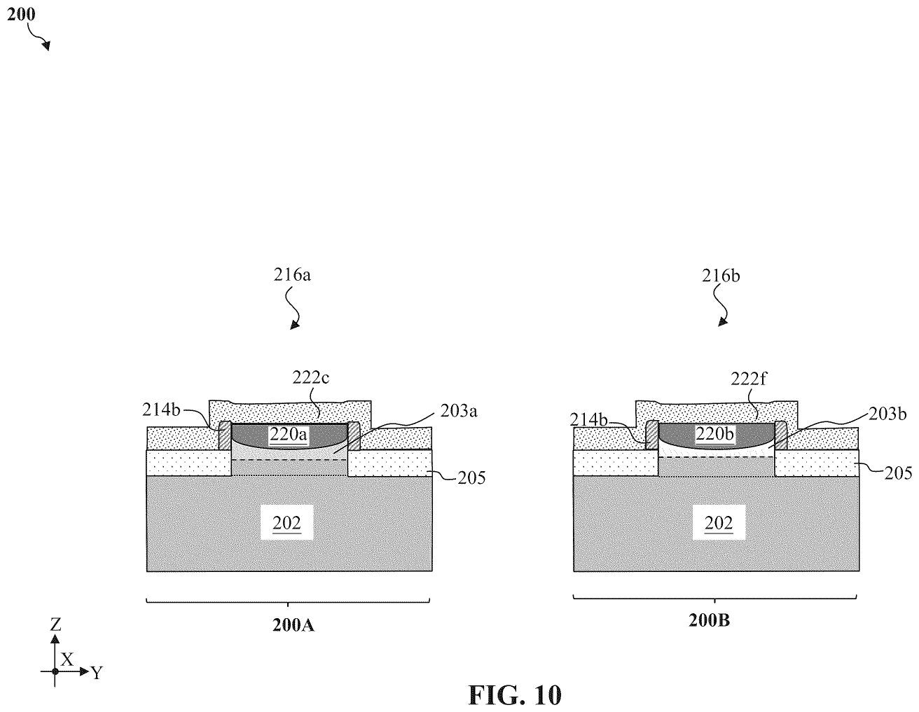

Referring now to FIGS. 1 and 9-10, method 100 includes a block 112 where an insulation layer 222 is deposited over the workpiece 200, including in the first region 200A and the second region 200B. FIG. 10 illustrates cross-sectional views of the workpiece 200 taken along line A-A and B-B as shown in FIG. 9, respectively. In the present embodiments, the insulation layer 222 is deposited by using a chemical vaper deposition (CVD), physical vaper deposition (PVD), atomic layer deposition (ALD) or other suitable processes, and the deposition thickness of the insulation layer 222 may be dependent on desired thicknesses of final bottom portions (e.g., 222c′ and 222f) of the insulation layer 222 formed in the source/drain openings 216a and 216b. In an embodiment, the insulation layer 222 is deposited by using a physical vaper deposition (PVD) process. Due to the properties of the PVD process, a portion of the insulation layer 222 formed on a top or planar surface are thicker than a portion of the insulation layer 222 formed on a side surface. More specifically, as depicted in FIG. 9 the insulation layer 222 includes a portion 222a formed over top surfaces of the dummy gate stacks 210 in the first region 200A, a portion 222b extending along exposed sidewall surfaces of the channel regions 204C of the fin-shaped structure 204a and sidewall surfaces of the gate spacers 214a, a portion 222c formed on the top surface of the semiconductor layer 220a. The insulation layer 222 also includes a portion 222d formed over top surfaces of the dummy gate stacks 210 in the second region 200B, a portion 222e extending along exposed sidewall surfaces of the channel regions 204C of the fin-shaped structure 204b and sidewall surfaces of the gate spacers 214a, a portion 222f formed on the top surface of the semiconductor layer 220b. For embodiments in which the insulation layer 222 is deposited by PVD, a thickness T1 of the portion 222a/222c/222d/222f is greater than a thickness T2 of the portion 222b/222e. In some embodiments, a thickness of the portion 222a/222d may be different from a thickness of the portion 222c/222f. It is noted, as depicted in FIG. 10, when viewed from the X direction, the portion 222c of the insulation layer 222 is also disposed on the dielectric isolation features 205 and extends along sidewall surfaces of the fin sidewall spacers 214b in the first region 200A, and the portion 222f of the insulation layer 222 is also disposed on the dielectric isolation features 205 and extends along sidewall surfaces of the fin sidewall spacers 214b in the second region 200B.

The insulation layer 222 may be formed of any suitable dielectric material so long as its composition is different from those of the channel layers (e.g., channel layers 208b, 208m, 208t), the sacrificial layers 206, the gate-top hard mask layer 213, the gate spacers 214a, and the inner spacer features 218 to allow selective removal by an etching process. In some embodiments, the insulation layer 222 may include silicon nitride (SiN), silicon oxynitride (SiON), silicon oxycarbonitride (SiOCN), silicon oxycarbide (SiOC), silicon carbonitride (SiCN), aluminum oxide, hafnium oxide, or other suitable materials. In an embodiment, the insulation layer 222 is oxygen-free and includes silicon nitride. A composition of the composition of the insulation layer 222 is different from a composition of the inner spacer features 218.

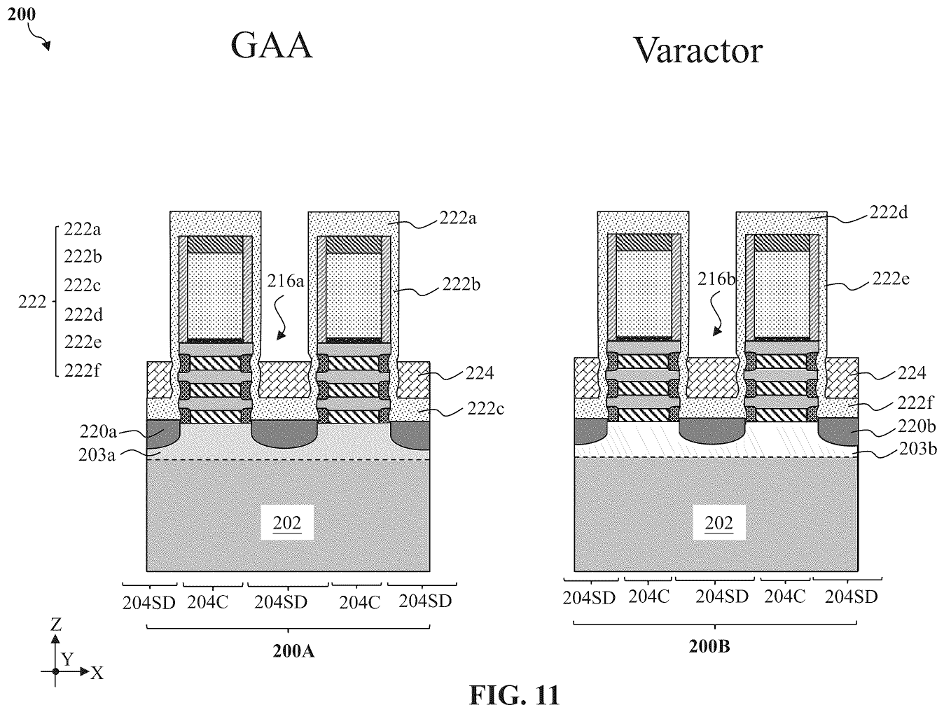

Referring now to FIGS. 1 and 11-13, method 100 includes a block 114 where portions of the insulation layer 222 are removed, thereby leaving bottom portions of the insulation layer in the source/drain openings 216a and 216b and on the undoped semiconductor layers 220a and 220b. In an example process, as depicted in FIG. 11, a mask layer 224 is formed to cover portions of the insulation layer 222. In the present embodiments, the mask layer 224 includes a bottom antireflective coating (BARC) layer and may include silicon oxynitride, a polymer, or any other suitable materials. In the present embodiments, the mask layer 224 covers the portion 222c, the portion 222f, and lower parts of the portions 222b and 222e of the insulation layer 222. As illustrated in FIG. 11, the mask layer 224 does not cover the portion 222a, the portion 222d, and upper parts of the portions 222b and 222e of the insulation layer 222. While using the mask layer 224 as an etch mask, a first etching process is performed to selectively remove portions of the insulation layer 222 not covered by the mask layer 224. The first etching process may be a dry etch process, a wet etch process, or a suitable etch process. After selectively removing the portions of the insulation layer 222 not covered by the mask layer 224, the mask layer 224 is selectively removed using a suitable etching process. In embodiments, after the removal of the mask layer 224, although not shown, the workpiece 200 includes the lower parts of the portions 222b and 222c, the portion 222c, and the portion 222f of the insulation layer 222.

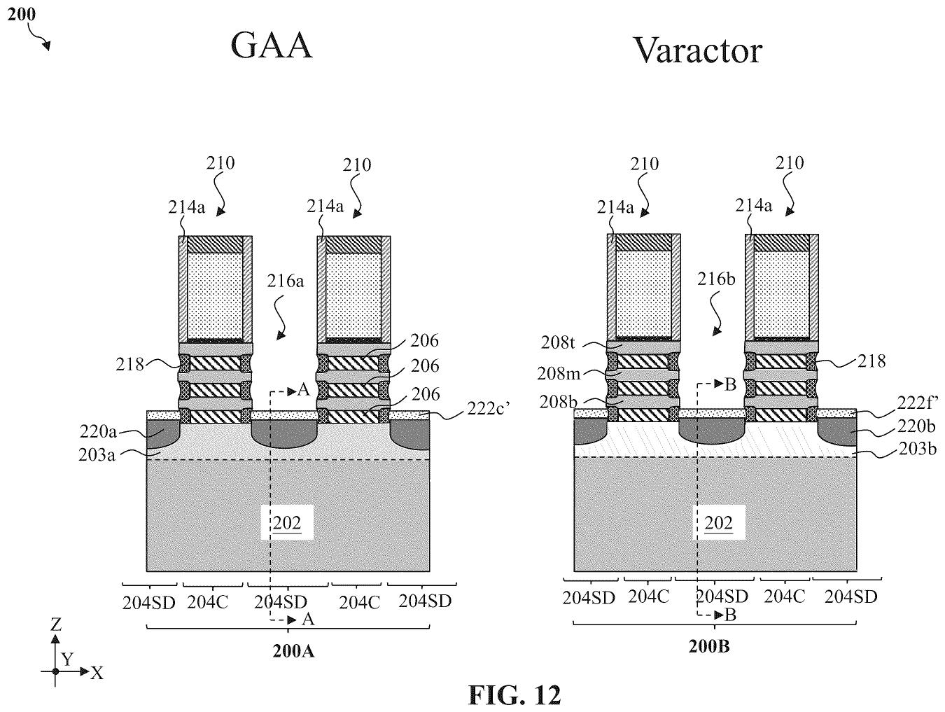

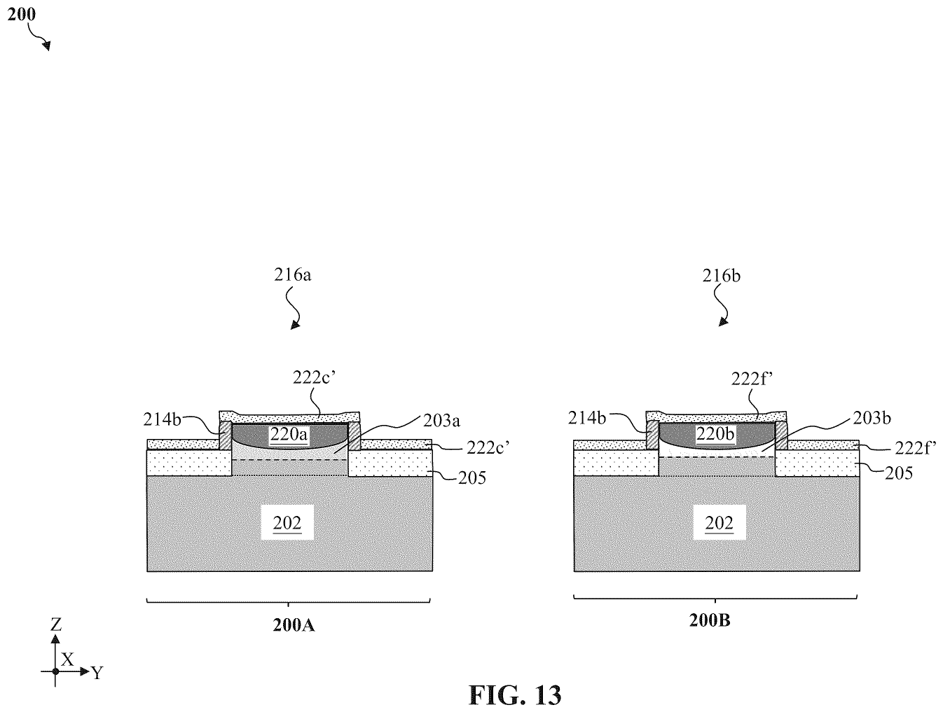

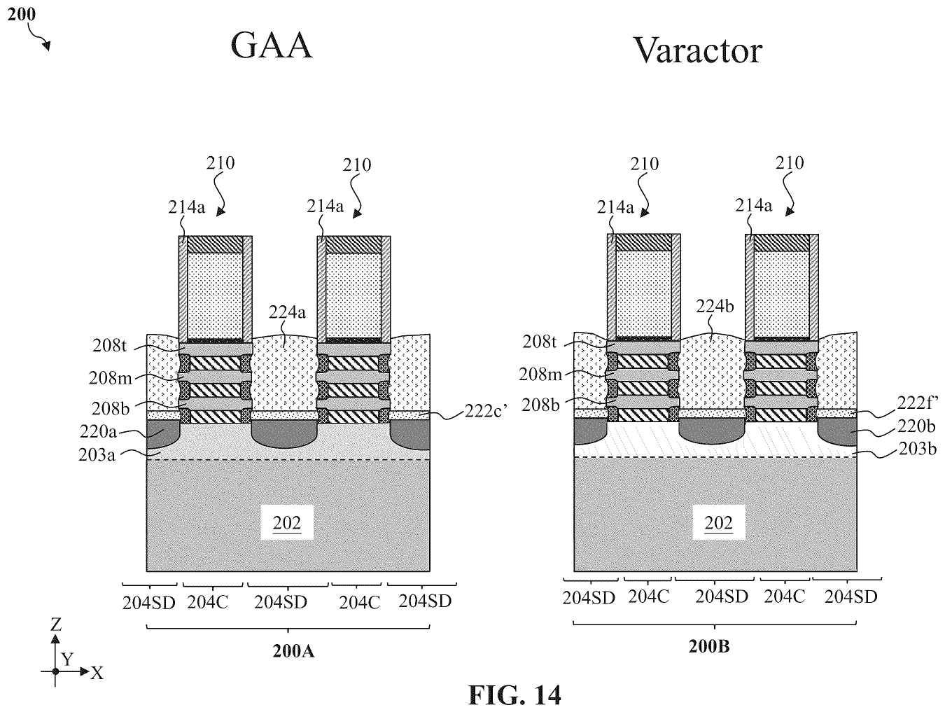

With reference to FIGS. 12 and 13, a second etching process is performed to remove the lower parts of the portions 222b and 222e of the insulation layer 222. FIG. 13 illustrates cross-sectional views of the workpiece 200 taken along line A-A and B-B as shown in FIG. 12, respectively. The second etching process is implemented to selectively etch back the insulation layer 222 without substantially etching the channel layers (e.g., the channel layers 208b, 208m, 208t) and sacrificial layers 206, the gate spacers 214a, the gate-top hard mask layer 213, and the inner spacer features 218. In an embodiment, the second etching process includes an isotropic etching process configured to selectively etch the insulation layer 222. The duration of the isotropic etching process may be controlled such that the lower parts of the portions 222b and 222e formed on the sidewall surfaces of the channel regions 204C are fully removed. Due to the performing of the isotropic etching process, the portions 222c and 222f of the insulation layer 222 are also slightly etched. The portions 222c and 222f of the insulation layer 222 after the performing of the second etching process may be referred to as dielectric layer 222c′ and dielectric layer 222f″, respectively. The top surface of the dielectric layer 222f may be above, coplanar with, or below the top surface of the bottommost inner spacer feature 218 of the inner spacer features 218. In an embodiment, the dielectric layer 222f′ has a thickness in a range between about 3 nm and 10 nm, and a thickness of the bottommost inner spacer feature 218 of the inner spacer features 218 is in a range between about 3 nm and 15 nm. The dielectric layer 222c′ in the first region 200A is formed between the to-be-formed source/drain features 224a (shown in FIG. 14) and the substrate 202, thereby substantially suppressing and/or eliminating any parasitic transistor formed between the metal gate structures 240 (shown in FIG. 17), source/drain features 224a, and underlying mesa structure(s) 202t, thereby reducing and/or blocking leakage current through the mesa structure(s) 202t. The dielectric layer 222f in the second region 200B is formed between the to-be-formed source/drain features 224b (shown in FIG. 14) and the substrate 202, thereby substantially eliminating current flow between the second well 203b and the source/drain features 224b and thus the second well 203b is electrically floating during operation. As a result, a tuning ratio of the varactor may be advantageously increased. In some embodiments, after the performing of the second etching process, as depicted in FIG. 13, the dielectric layer 222c′ is also formed directly on the STI features 205 in the first region 200A, and the dielectric layer 222f is also formed directly on the STI features 205 in the second region 200B.

Referring now to FIGS. 1 and 14, method 100 includes a block 116 where source/drain features 224a and 224b are formed in the source/drain openings 216a and 216b, respectively. Source/drain feature(s) may refer to a source or a drain, individually or collectively dependent upon the context. The source/drain features 224a are coupled to the channel layers (e.g., channel layers 208t, 208m, 208b) of the channel regions 204C in the first region 200A. The source/drain features 224b are coupled to the channel layers (e.g., channel layers 208t, 208m, 208b) of the channel regions 204C in the second region 200B. The source/drain features 224a and 224b each may be epitaxially and selectively formed from exposed sidewalls of the channel layers (e.g., channel layers 208t, 208m, 208b) by using an epitaxial process, such as vapor phase epitaxy (VPE), ultrahigh vacuum chemical vapor deposition (UHV-CVD), molecular-beam epitaxy (MBE), and/or other suitable processes.

Each of the source/drain features 224a and 224b may include N-type source/drain features and/or P-type source/drain features dependent upon types of transistors and varactors. Example N-type source/drain features may include silicon, phosphorus-doped silicon, arsenic-doped silicon, antimony-doped silicon, or other suitable material and may be in-situ doped during the epitaxial process by introducing an N-type dopant, such as phosphorus, arsenic, or antimony, or ex-situ doped using a junction implant process. Example P-type source/drain features may include germanium, gallium-doped silicon germanium, boron-doped silicon germanium, or other suitable material and may be in-situ doped during the epitaxial process by introducing a P-type dopant, such as boron or gallium, or ex-situ doped using a junction implant process. In some embodiments, each of the source/drain features 224a and the source/drain features 224b may include multiple semiconductor layers with different doping concentrations. For example, each of the source/drain features 224a and the source/drain features 224b may include a lightly doped semiconductor layer and a heavily doped semiconductor layer disposed over the lightly doped semiconductor layer.

In the present embodiment, the first region 200A of the workpiece 200 will be fabricated into GAA transistors, and the second region 200B of the workpiece 200 will be fabricated into varactors. A doping polarity of the source/drain features 224a is different from the doping polarity of the first well 203a, and a doping polarity of the source/drain features 224b is the same as the doping polarity of the second well 203b. In a first embodiment, the first well 203a is a P well, the source/drain features 224a are N-type source/drain features; the second well 203b is an N well, and the source/drain features 2224b are N-type source/drain features. In a second embodiment, the first well 203a is an N well, the source/drain features 224a are P-type source/drain features; the second well 203b is an N well, and the source/drain features 2224b are N-type source/drain features. In a third embodiment, the first well 203a is a P well, the source/drain features 224a are N-type source/drain features; the second well 203b is a P well, the source/drain features 224b are P-type source/drain features. In a fourth embodiment, the first well 203a is an N well, the source/drain features 224a are P-type source/drain features; the second well 203b is a P well, the source/drain features 224b are P-type source/drain features. It is understood that, for embodiments in which the source/drain feature 224a and 224b have the same doping popularity, they may be formed simultaneously or in any sequential order; and for embodiments in which the source/drain feature 224a and 224b have different doping popularities, they may be formed in any sequential order.

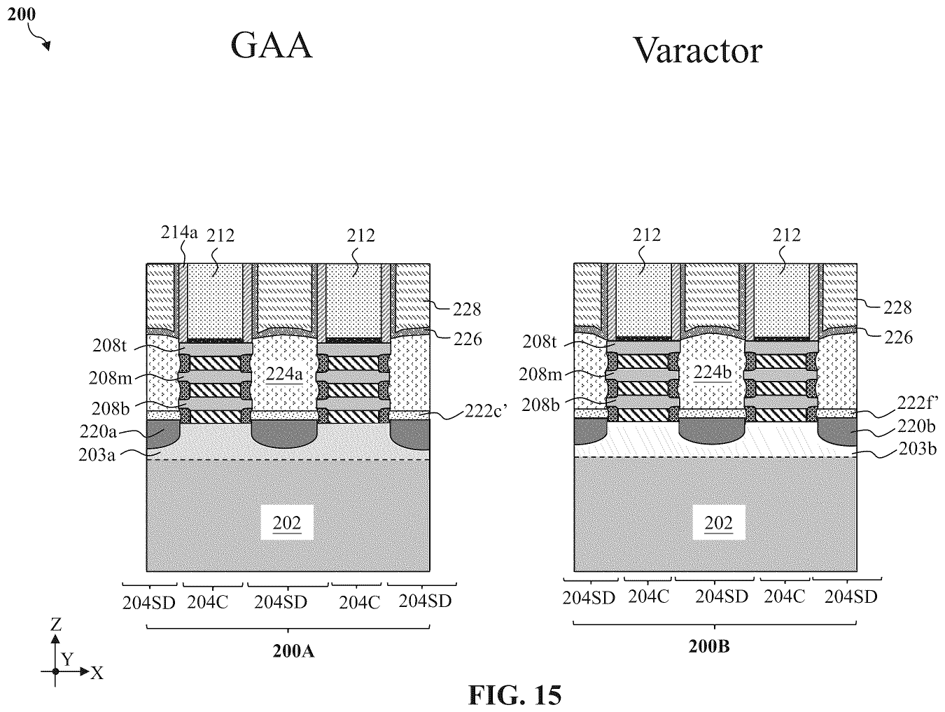

Referring now to FIGS. 1 and 15, method 100 includes a block 118 where a contact etch stop layer (CESL) 226 and an interlayer dielectric (ILD) layer 228 are deposited over the workpiece 200. The CESL 226 may include silicon nitride, silicon oxynitride, and/or other suitable materials and may be formed by atomic layer deposition (ALD) process, plasma-enhanced chemical vapor deposition (PECVD) process and/or other suitable deposition or oxidation processes. The ILD layer 228 is deposited by a flowable CVD (FCVD), a CVD process, a physical vapor deposition (PVD) process, or other suitable deposition technique over the workpiece 200 after the deposition of the CESL 226. The ILD layer 228 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. After depositing the CESL 226 and the ILD layer 228, a planarization process (e.g., chemical mechanical polishing CMP) is performed to remove excess materials (e.g., the gate-top hard mask layers 213 and portions of the gate spacers 214a in direct contact with the gate-top hard mask layers 213) to expose the dummy gate electrode layers 212 of the dummy gate stacks 210.

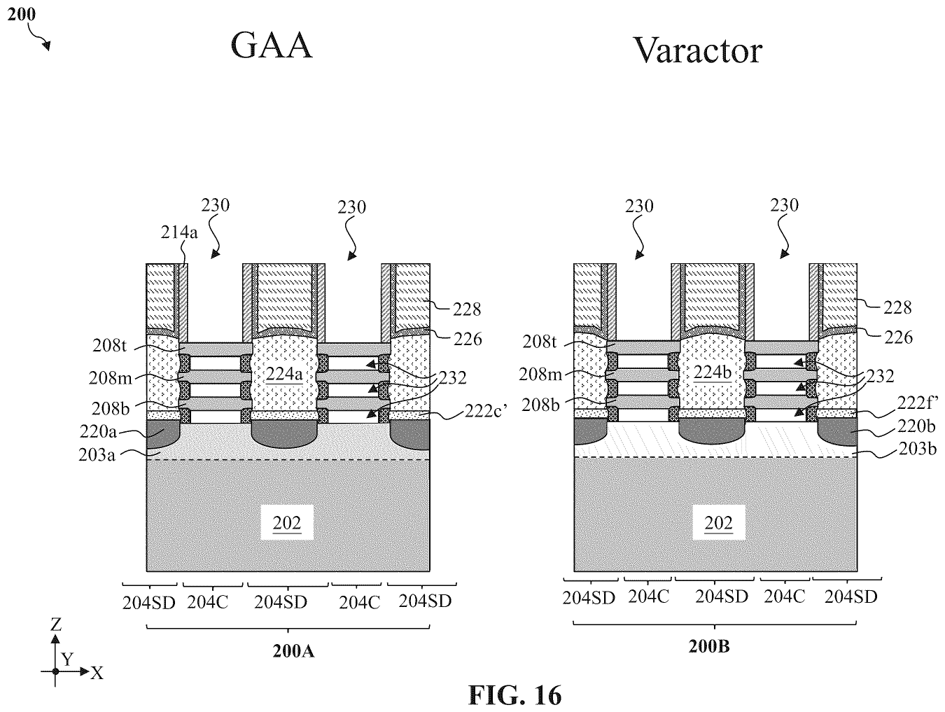

Referring now to FIGS. 1 and 16-17, method 100 includes a block 120 where the dummy gate stacks 210 and the sacrificial layers 206 are replaced by metal gate structures 240/242. With reference to FIG. 16, the dummy gate stacks 210 are selectively removed to form gate trenches 230 in the first region 200A and the second region 200B. An etching process may be implemented to selectively remove the dummy gate electrode layer 212 and the dummy gate dielectric layer 211 without substantially removing the gate spacers 214a. The etching process may be a dry etching process, a wet etching process, or combinations thereof that implements a suitable etchant. After the removal of the dummy gate stacks 210, the sacrificial layers 206 in the channel regions 204C are selectively removed to release the channel layers (e.g., channel layers 208t, 208m, 208b) as channel members (e.g., channel members 208t, 208m, 208b). The selective removal of the sacrificial layers 206 forms openings 232 under the gate trenches 230. The sacrificial layers 206 may be removed using selective dry etching process or selective wet etching process. The selective dry etching process may include use of one or more fluorine-based etchants, such as fluorine gas or hydrofluorocarbons. The selective wet etching process may include an APM etch (e.g., ammonia hydroxide-hydrogen peroxide-water mixture).

With reference to FIG. 17, after the removal of the dummy gate stacks 210 and the sacrificial layers 206, metal gate structures 240 are formed in the gate trenches 230 and openings 232 in the first region 200A, and metal gate structures 242 are formed in the gate trenches 230 and openings 232 the second region 200B. In an example process, the metal gate structures 240 and the metal gate structures 242 are formed simultaneously. That is, the metal gate structures 240 and the metal gate structures 242 have same structure and composition. Each of the metal gate structures 240/242 includes a first portion 240a/242a formed in the gate trenches 230 and a second portion 240b/242b formed in the openings 232.

The formation of the metal gate structures 242 includes forming an interfacial layer 243 to wrap around and over each of the channel members (e.g., channel members 208b, 208m, 208t). The interfacial layer 243 may include silicon oxide or other suitable material. The interfacial layer 243 may be formed using a suitable method, such as atomic layer deposition (ALD), chemical vapor deposition (CVD), thermal oxidation, or other suitable method. In an embodiment, the interfacial layer 243 is formed by thermal oxidation and is thus only formed on surfaces of the channel members (e.g., channel members 208t. 208m, 208b), as depicted by the enlarged portion of the second portion 242b. That is, the interfacial layer 243 does not extend along sidewall surfaces of the gate spacers 214a and does not extend along sidewall surfaces of the inner spacer features 218. In another embodiment, the interfacial layer 243 is formed by ALD and is thus conformally formed on surfaces of the workpiece 200. That is, the interfacial layer 243 also extends along sidewall surfaces of the gate spacers 214a and sidewall surfaces of the inner spacer features 218. The second portion 242b of the metal gate structure 242 may include two configurations, depending on the method of forming the interfacial layer 243 (e.g., by deposition or by thermal oxidation. Different configurations of the enlarged first portion 242a and enlarged second portion 242b of the metal gate structure 242 are depicted in FIG. 17).

Still referring to FIG. 17, after forming the interfacial layer 243, a dielectric layer 244 is formed over the workpiece 200 to wrap around and over each of the channel members (e.g., channel members 208t, 208m, 208b). In an embodiment, the dielectric layer 244 is deposited conformally over the workpiece 200. The term “conformally” may be used herein for ease of description of a layer having a substantially uniform thickness over various regions. In some embodiments, the dielectric layer 244 is high-k dielectric layer as its dielectric constant is greater than that of silicon dioxide (˜3.9). In some implementations, the dielectric layer 244 may include titanium oxide (TiO₂), tantalum oxide (Ta₂O₅), hafnium silicon oxide (HfSiO₄), zirconium oxide (ZrO₂), zirconium silicon oxide (ZrSiO₂), aluminum oxide (Al₂O₃), zirconium oxide (ZrO), yttrium oxide (Y₂O₃), SrTiO₃ (STO), BaTiO₃ (BTO), BaZrO, aluminum silicon oxide (AlSiO), hafnium tantalum oxide (HfTaO), hafnium titanium oxide (HfTiO), (Ba,Sr) TiO₃ (BST), silicon nitride (SiN), silicon oxynitride (SiON), combinations thereof, or other suitable material. The dielectric layer 244 and the interfacial layer 243 may be collectively referred to as a gate dielectric layer.

Still referring to FIG. 17, after forming the dielectric layer 244, operations in block 120 also includes forming a gate electrode 245 in the gate trenches 230 and openings 232. The gate electrode 245 may be a multi-layer structure that includes at least one work function layer and a metal fill layer. By way of example, the at least one work function layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), or tantalum carbide (TaC). For embodiments in which the varactors include N-type source/drain features 224b, the gate electrode 245 of the metal gate structure 242 may include at least an N-type work function layer. The N-type work function layer may include titanium-aluminum based metal, such as titanium aluminum carbon (TiAlC) or titanium aluminum (TiAl). For embodiments in which the varactors include P-type source/drain features 224b, the gate electrode 245 of the metal gate structure 242 may include at least a P-type work function layer. The P-type work function layer may include titanium nitride (TiN), tungsten carbonitride (WCN), tantalum nitride (TaN), or molybdenum nitride (MoN). The metal fill layer may include aluminum (Al), tungsten (W), nickel (Ni), titanium (Ti), ruthenium (Ru), cobalt (Co), platinum (Pt), tantalum silicon nitride (TaSiN), copper (Cu), other refractory metals, or other suitable metal materials or a combination thereof. In various embodiments, the gate electrode 245 may be formed by ALD, PVD, CVD, e-beam evaporation, or other suitable process. In various embodiments, a planarization process, such as a chemical mechanical polishing (CMP) process, may be performed to remove excess materials over the ILD layer 228 to provide a substantially planar top surface of the first portion 242a of the gate structure 242 and facilitate the performing of further processes. In the above embodiments, the metal gate structures 240 and 242 are formed simultaneously and have same compositions. In some other embodiments, the metal gate structures 240 and 242 may be formed in any sequential order, and may have same or different compositions and/or structures, depending upon the types of the GAA transistors and the varactors.

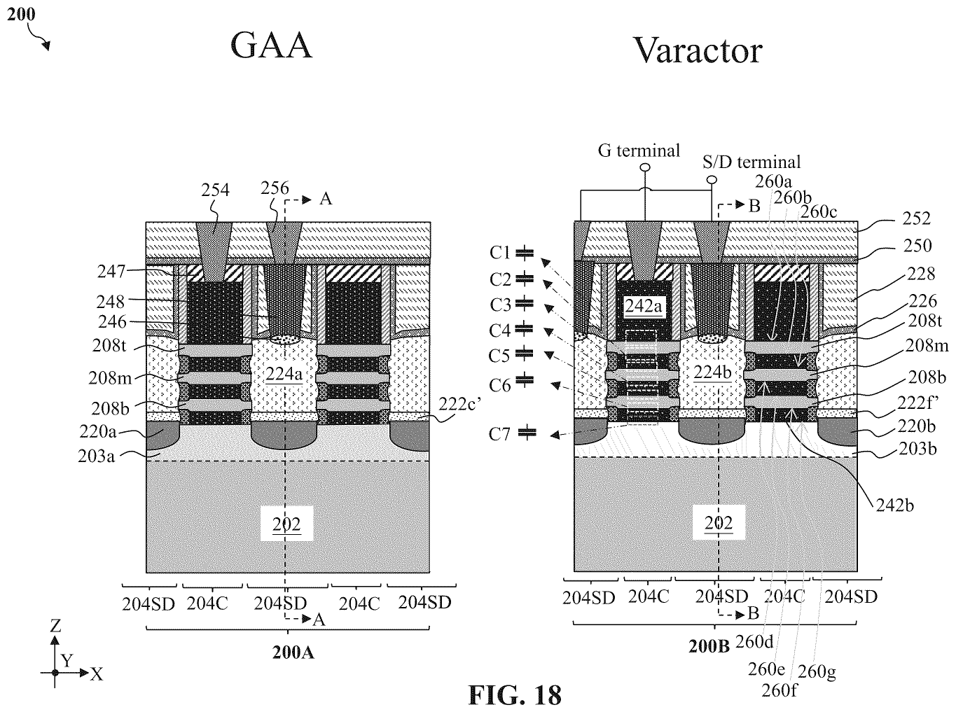

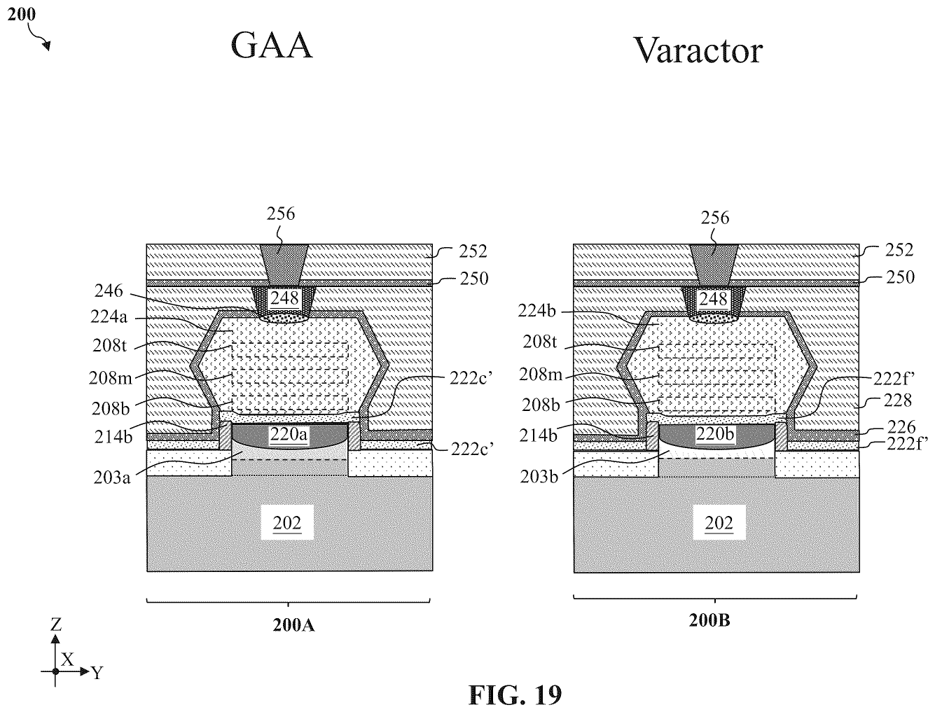

Referring to FIGS. 1 and 18-19, method 100 includes a block 122 where further processes are performed. FIG. 19 illustrates cross-sectional views of the workpiece 200 taken along line A-A and B-B as shown in FIG. 18. Such further processes may include recessing the first portions 240a/242a of the metal gate structures 240/242 and forming self-aligned cap (SAC) dielectric layers 244 over the recessed metal gate structures 240/242. In an embodiment, a dielectric material layer is deposited over the workpiece 200 and a planarization process may be followed to remove excess dielectric material layer to form the SAC dielectric layers 247. The dielectric material layer may be formed of hafnium silicide, silicon oxycarbide, aluminum oxide, zirconium silicide, aluminum oxynitride, zirconium oxide, hafnium oxide, titanium oxide, zirconium aluminum oxide, zinc oxide, tantalum oxide, lanthanum oxide, yttrium oxide, tantalum carbonitride, silicon nitride, silicon oxycarbonitride, silicon, zirconium nitride, or silicon carbonitride. In an embodiment, the dielectric material layer is formed of silicon nitride. Such further processes may also include forming device-level contacts, such as source/drain contacts 248. In an example process, contact openings are formed to extend through the ILD layer 228 and the CESL 226 to expose the source/drain features 224a/224b. Silicide layers 246 may be formed in the contact openings and in direct contact with the source/drain features 224a/224b. The source/drain contacts 248 may be then formed on the silicide layers 246 and in the contact openings. Such further processes may also include forming gate contact vias 254 and source/drain vias 256. In an example process, an etch stop layer 250 and an ILD layer 252 are formed over the gate structures 240 and 242, the gate contact vias 254 are formed to extend through the ILD layer 252, the etch stop layer 250, and the SAC dielectric layers 247 to electrically connect to the gate structures 240/242; and the source/drain vias 256 are formed to extend through the ILD layer 252 and the etch stop layer 250 to electrically connect to the source/drain contacts 248. Such further processes may also include forming a multi-layer interconnect (MLI) structure (not depicted) over the workpiece 200. The MLI may include various interconnect features, such as vias and conductive lines, disposed in dielectric layers, such as etch-stop layers and ILD layers. In some embodiments, the vias are vertical interconnect features configured to interconnect the device-level contacts.

During operation, as shown in FIG. 18, the source/drain features 224b of the varactor 200B are connected to a common S/D terminal, and the gate structure 242 of the varactor 200B is connected to a G (gate) terminal, thereby forming a two-terminal capacitor. The S/D terminal and the G terminal correspond to the two terminals of a capacitor.

The minimum capacitance Cmin of the varactor 200B is a function of the total capacitance of a parasitic capacitance Cco associated with the source/drain contacts 248 and the first portion 242a of the gate structure 242, a parasitic capacitance Cof associated with the source/drain features 224b and the second portion 242b of the gate structure 242, a parasitic capacitance Cgd caused by the vertical overlap between the source/drain features 224b and the first portion 242a of the gate structure 242, and a parasitic capacitance Cgb caused by the vertical overlap between the gate structure 242 and the bulk substrate 202. By electrically floating the second well 203b and the substrate 202, the minimum capacitance Cmin of the varactor 200B is reduced due to the disablement of the capacitance Cgb.

Due to the existence of the gate dielectric layer, capacitances are formed near the interfaces between the gate structure 242 and semiconductor layers (e.g., the channel members and the substrate 202). For embodiments in which the varactor 200B includes three channel members 208b, 208m, and 208t, there are seven interfaces 260a, 260b, 260c, 260d, 260c, 260f, 260g between the gate structure 242 and semiconductor layers, and thus seven capacitances C1, C2, C3, C4, C5, C6, and C7 are formed. It is noted that, the interface 260g is between the gate structure 242 and the second well 203b, and the associated capacitance C7 is related to the bulk substrate 202. In some embodiments, the capacitance C7 is less than any of the capacitances C1˜C6. The maximum capacitance Cmax of the varactor 200B is a function of the sum of the capacitance C1, the capacitance C2, the capacitance C3, the capacitance C4, the capacitance C5, the capacitance C6, and the capacitance C7. More precisely, the maximum capacitance Cmax includes the capacitance C1, the capacitance C2, the capacitance C3, the capacitance C4, the capacitance C5, the capacitance C6, and the capacitance C7, and the minimum capacitance Cmin. By forming the dielectric layer 222f to block the current path between the second well 203b and the source/drain features 224b, the second well 203b and the substrate 202 are electrically floating, and the maximum capacitance Cmax of the varactor 200B is thus reduced due to the disablement of the capacitance C7 and the disablement of Cgb. As such, the maximum capacitance Cmax and the minimum capacitance Cmin of the varactor 200B are both reduced, compared with varactor that does not include the dielectric layer 222f. However, the bulk substrate 202 contributes more to the minimum capacitance Cmin than it contributes to the maximum capacitance Cmax. In other words, a percentage of the Cgb to Cmin (i.e., Cgb/Cmin) is greater than a percentage of a sum of C7 and Cgb to Cmax (i.e., (C7+Cgb)/Cmax). Thus, when floating the second well 203a, the maximum capacitance Cmax is less reduced than that of the minimum capacitance Cmin. Put differently, the extent at which the minimum capacitance Cmin is reduced is greater than the extent at which the maximum capacitance Cmax is reduced. As a result, a tuning ratio (i.e., Cmax/Cmin) of the varactor 200B is increased, thereby providing the varactor a larger frequency tuning range.

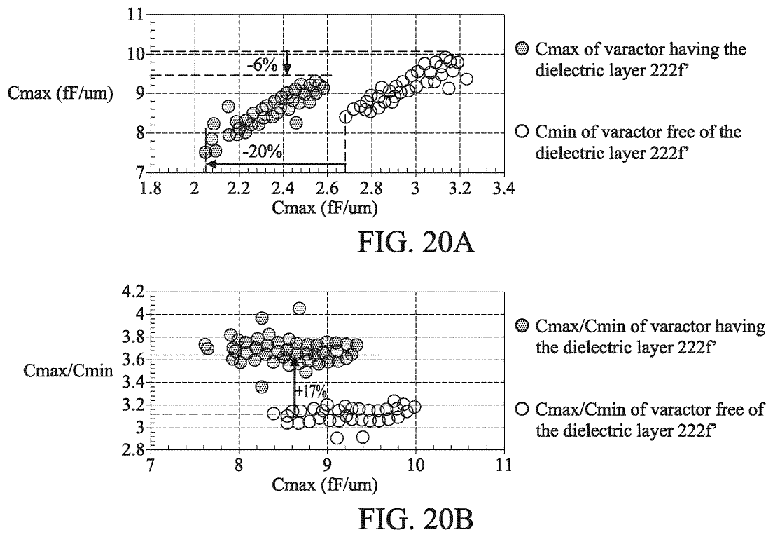

FIG. 20A illustrates corresponding simulation results that show the reduction of the maximum capacitance Cmax and the reduction of the minimum capacitance Cmin. FIG. 20B illustrates corresponding simulation results that show the reduction of the maximum capacitance Cmax and the increase of the tuning ratio (i.e., Cmax/Cmin). More specifically, compared with varactor that does not include the dielectric layer 222f′, the minimum capacitance Cmin is decreased by about 15% to about 20%, the maximum capacitance Cmax is decreased by about 3% to about 10%, and the tuning ratio (i.e., Cmax/Cmin) is increased by about 10% to about 25%.

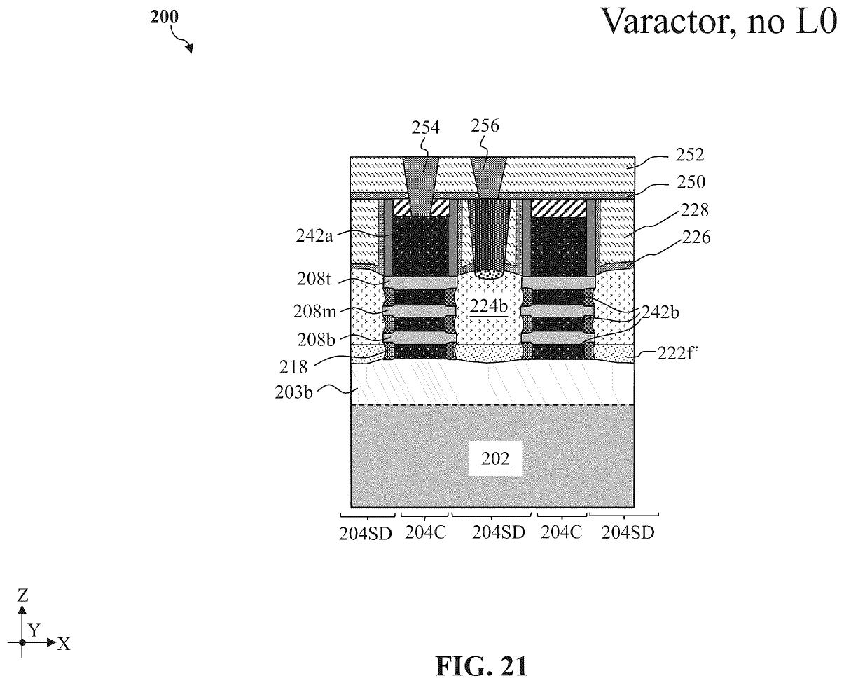

In the above embodiments described with reference to FIGS. 8-19, the dielectric layer 222f is in direct contact with the undoped semiconductor layer 220b. In some alternative embodiments, for example, in embodiment represented by FIG. 21, there is no semiconductor layer 220b formed vertically between the substrate 202 and the source/drain features 224b, and the dielectric layer 222f of varactor 200B is in direct contact with the substrate 202. In an embodiment, the dielectric layer 222f extends into the second well 203b. A top surface of the dielectric layer 222f may be coplanar with, above, or below a bottom surface of the bottommost channel member (e.g., the channel member 208b) of the number of channel members (e.g., the channel members 208b, 208m, 208t). An entirety of the sidewall surface of the dielectric layer 222f may be in direct contact with the bottommost inner spacer feature of the number of inner spacer features 218.

Although not intended to be limiting, one or more embodiments of the present disclosure provide many benefits to a semiconductor structure and the formation thereof. For example, the present disclosure provides a varactor having an increased tuning ratio and methods of forming the same. In an embodiment, a dielectric layer is formed between the substrate and the source/drain feature, thereby blocking a current path between the source/drain features and the well region formed in the substrate to set the well region to be electrically floating. As a result, compared with varactors that are free of the dielectric layer, the varactors of the present disclosure provide a higher tuning ratio and improved performance. In addition, the present methods of the present disclosure are compatible with conventional complementary metal-oxide-semiconductor (CMOS) processes and may be easily integrated into existing manufacturing flow.

The present disclosure provides for many different embodiments. Semiconductor structures and methods of fabrication thereof are disclosed herein. In one exemplary aspect, the present disclosure is directed to a semiconductor device. The semiconductor device includes a doped region in a substrate and comprising a first-type dopant, a plurality of nanostructures disposed directly over the doped region, a gate structure wrapping around each nanostructure of the plurality of nanostructures, a first epitaxial feature and a second epitaxial feature coupled to the plurality of nanostructures, wherein each of the first epitaxial feature and the second epitaxial feature comprises the first-type dopant, a first insulation feature disposed between the first epitaxial feature and the doped region, and a second insulation feature disposed between the second epitaxial feature and the doped region.

In some embodiments, the semiconductor device may also include an undoped semiconductor layer disposed between the first insulation feature and the doped region. In some embodiments, the semiconductor device may also include outer spacer features extending along sidewalls of a portion of the gate structure that is disposed over the plurality of nanostructures, and inner spacer features disposed adjacent to portions of the gate structure that wrap around the plurality of nanostructures. In some embodiments, the first insulation feature may be in direct contact with a bottommost inner spacer feature of the inner spacer features. In some embodiments, a top surface of the first insulation feature may be above a top surface of the bottommost inner spacer feature of the inner spacer features. In some embodiments, the first insulation feature and the second insulation feature may include same composition. In some embodiments, the composition of the first insulation feature and the second insulation feature may be different from a composition of the inner spacer features. In some embodiments, the doped region may include an N-type well, the first epitaxial feature and the second epitaxial feature comprise N-type doped silicon, and the gate structure may include an N-type work function layer. In some embodiments, the doped region may include a P-type well, the first epitaxial feature and the second epitaxial feature comprise P-type doped silicon, and the gate structure may include a P-type work function layer. In some embodiments, the first insulation feature and the second insulation feature are in direct contact with the doped region.

In another exemplary aspect, the present disclosure is directed to a varactor. The varactor includes a substrate comprising an N well, a plurality of nanostructures disposed directly over the N well, a gate structure comprising a first portion wrapping around each nanostructure of the plurality of nanostructures and a second portion disposed over the plurality of nanostructures, and N-type source/drain features coupled to the plurality of nanostructures, wherein the N-type source/drain features are electrically isolated from the N well by a dielectric layer.

In some embodiments, the varactor may also include an undoped semiconductor layer extending into the N well and disposed directly under the dielectric layer. In some embodiments, the varactor may also include a plurality of inner spacer features disposed between the first portion of the gate structure and the N-type source/drain features, wherein the dielectric layer is in direct contact with a bottommost inner spacer feature of the plurality of inner spacer features. In some embodiments, the second portion of the gate structure may include an interfacial layer in direct contact with a topmost nanostructure of the plurality of nanostructures, an N-type work function layer over the interfacial layer, and a U-shape high-k dielectric layer extending along sidewall and bottom surfaces of the N-type work function layer. In some embodiments, the varactor may also include gate spacers extending along sidewalls of the second portion of the gate structure, an isolation feature over the substrate and adjacent to the N well, fin sidewall spacers over the isolation feature and in direct contact with the N well, wherein the gate spacers and fin sidewall spacers comprise a same composition. In some embodiments, dielectric layer is further in direct contact with the isolation feature.

In yet another exemplary aspect, the present disclosure is directed to a method. The method includes providing a workpiece comprising a substrate comprising a well region having a first doping polarity, a vertical stack of alternating channel layers and sacrificial layers over and in direct contact with the well region, and a dummy gate stack intersecting with the vertical stack. The method also includes recessing portions of the vertical stack not covered by the dummy gate stack to form source/drain trenches, the source/drain trenches exposing the well region, forming a dielectric layer to fill a lower portion of the source/drain trenches, forming source/drain features on the dielectric layer to fill an upper portion of the source/drain trenches, the source/drain features comprising the first doping polarity, selectively removing the dummy gate stack to form a gate trench, selectively removing the sacrificial layers of the vertical stack to form gate openings, and forming a gate structure in the gate trench and gate openings. In some embodiments, the forming of the dielectric layer may include depositing a dielectric material layer over the workpiece, the dielectric material layer comprising a first portion filling the lower portion of the source/drain trenches, a second portion directly over the dummy gate stack, and a third portion extending along sidewalls of the source/drain trenches, and removing the second portion and third portion of the dielectric material layer, thereby forming the dielectric layer. In some embodiments, the workpiece further may include an isolation feature disposed between the vertical stack and another vertical stack of alternating channel layers and sacrificial layers, wherein a portion of the dielectric layer is disposed directly on the isolation feature. In some embodiments, the well region and the source/drain features are N-type features, and wherein the forming of the gate structure may include conformally depositing a gate dielectric layer over the workpiece and conformally depositing an N-type work function layer over the gate dielectric layer.

The foregoing has outlined features of several embodiments so that those skilled in the art may better understand the detailed description that follows. Those skilled in the art should appreciate that they may readily use the present disclosure as a basis for designing or modifying other processes and structures for conducting the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure. For example, by implementing different thicknesses for the bit-line conductor and word line conductor, one can achieve different resistances for the conductors. However, other techniques to vary the resistances of the metal conductors may also be utilized as well.

What is claimed is:

1. A semiconductor device, comprising:
a doped region in a substrate and comprising a first-type dopant;
a plurality of nanostructures disposed directly over the doped region;
a gate structure wrapping around each nanostructure of the plurality of nanostructures;
a first epitaxial feature and a second epitaxial feature coupled to the plurality of nanostructures, wherein each of the first epitaxial feature and the second epitaxial feature comprises the first-type dopant;
a first insulation feature disposed between the first epitaxial feature and the doped region; and
a second insulation feature disposed between the second epitaxial feature and the doped region.

2. The semiconductor device of claim 1, further comprising:
an undoped semiconductor layer disposed between the first insulation feature and the doped region.

3. The semiconductor device of claim 1, further comprising:
outer spacer features extending along sidewalls of a portion of the gate structure that is disposed over the plurality of nanostructures; and
inner spacer features disposed adjacent to portions of the gate structure that wrap around the plurality of nanostructures.

4. The semiconductor device of claim 3, wherein the first insulation feature is in direct contact with a bottommost inner spacer feature of the inner spacer features.

5. The semiconductor device of claim 3, wherein a top surface of the first insulation feature is above a top surface of a bottommost inner spacer feature of the inner spacer features.

6. The semiconductor device of claim 3, wherein the first insulation feature and the second insulation feature comprise a same composition.

7. The semiconductor device of claim 6, wherein the composition of the first insulation feature and the second insulation feature is different from a composition of the inner spacer features.

8. The semiconductor device of claim 1, wherein the doped region comprises an N-type well, the first epitaxial feature and the second epitaxial feature comprise N-type doped silicon, and the gate structure comprises an N-type work function layer.

9. The semiconductor device of claim 1, wherein the doped region comprises a P-type well, the first epitaxial feature and the second epitaxial feature comprise P-type doped silicon, and the gate structure comprises a P-type work function layer.

10. The semiconductor device of claim 1, wherein the first insulation feature and the second insulation feature are in direct contact with the doped region.

11. A varactor, comprising:
a substrate comprising an N well;
a plurality of nanostructures disposed directly over the N well;
a gate structure comprising a first portion wrapping around each nanostructure of the plurality of nanostructures and a second portion disposed over the plurality of nanostructures; and
N-type source/drain features coupled to the plurality of nanostructures, wherein the N-type source/drain features are electrically isolated from the N well by a dielectric layer.

12. The varactor of claim 11, further comprising:
an undoped semiconductor layer extending into the N well and disposed directly under the dielectric layer.

13. The varactor of claim 11, further comprising:
a plurality of inner spacer features disposed between the first portion of the gate structure and the N-type source/drain features,
wherein the dielectric layer is in direct contact with a bottommost inner spacer feature of the plurality of inner spacer features.

14. The varactor of claim 11, wherein the second portion of the gate structure comprises:
an interfacial layer in direct contact with a topmost nanostructure of the plurality of nanostructures;
an N-type work function layer over the interfacial layer; and
a U-shape high-k dielectric layer extending along sidewall and bottom surfaces of the N-type work function layer.

15. The varactor of claim 11, further comprising:
gate spacers extending along sidewalls of the second portion of the gate structure;
an isolation feature over the substrate and adjacent to the N well;
fin sidewall spacers over the isolation feature and in direct contact with the N well, wherein the gate spacers and fin sidewall spacers comprise a same composition.

16. The varactor of claim 15, wherein the dielectric layer is further in direct contact with the isolation feature.

17. A method, comprising:
providing a workpiece comprising:
a substrate comprising a well region having a first doping polarity,
a vertical stack of alternating channel layers and sacrificial layers over and in direct contact with the well region, and
a dummy gate stack intersecting with the vertical stack,
recessing portions of the vertical stack not covered by the dummy gate stack to form source/drain trenches, the source/drain trenches exposing the well region;
forming a dielectric layer to fill a lower portion of the source/drain trenches;
forming source/drain features on the dielectric layer to fill an upper portion of the source/drain trenches, the source/drain features comprising the first doping polarity;
selectively removing the dummy gate stack to form a gate trench;
selectively removing the sacrificial layers of the vertical stack to form gate openings; and
forming a gate structure in the gate trench and gate openings.

18. The method of claim 17, wherein the forming of the dielectric layer comprises:
depositing a dielectric material layer over the workpiece, the dielectric material layer comprising a first portion filling the lower portion of the source/drain trenches, a second portion directly over the dummy gate stack, and a third portion extending along sidewalls of the source/drain trenches; and
removing the second portion and third portion of the dielectric material layer, thereby forming the dielectric layer.

19. The method of claim 17, wherein the workpiece further comprises:
an isolation feature disposed between the vertical stack and another vertical stack of alternating channel layers and sacrificial layers,
wherein a portion of the dielectric layer is disposed directly on the isolation feature.

20. The method of claim 17, wherein the well region and the source/drain features are N-type features, and wherein the forming of the gate structure comprises:
conformally depositing a gate dielectric layer over the workpiece; and
conformally depositing an N-type work function layer over the gate dielectric layer.
